(19) United States
(12) Patent Application Publication
(10) Pub. No.: US 2024/0201580 A1
(43) Pub. Date: Jun. 20, 2024

(54) Photomask handling assembly for atmospheric pressure plasma chamber

(71) Applicant: Applied Materials, Inc., Santa Clara, CA (US)

(72) Inventors: Nolan Layne ZIMMERMAN, Kalispell, MT (US); Banqiu WU, San Jose, CA (US)

(21) Appl. No.: 18/082,948

(22) Filed: Dec. 16, 2022

(51) Int. Cl. G03F 1/82; G03F 1/66; G03F 9/00

(52) U.S. Cl. CPC G03F 1/82; G03F 1/66; G03F 9/7046

(57) ABSTRACT

An automatic photomask handling assembly is employed for holding a photomask for cleaning processes in an atmospheric pressure plasma (APP) chamber. The automatic photomask handling assembly includes a set of stationary standoffs with each of the stationary standoffs having a first end solidly mounted to the photomask handling assembly and a second end that contacts an underside of a photomask. The automatic photomask handling assembly also has a handling stage that holds the photomask for processing. The handling stage has a set of through openings that allow the set of stationary standoffs to pass through the handling stage as the handling stage moves vertically. The handling stage also has a set of plates that automatically clamp and unclamp a photomask as the handling stage moves vertically. The set of plates completely surrounds the photomask such that the clamped photomask and the set of plates form a continuous surface.

### FIELD

Embodiments of the present principles generally relate to semiconductor processing of semiconductor substrates.

### BACKGROUND

Atmospheric pressure (AP) plasma chambers can be used to clean photomasks for semiconductor manufacturing. The non-vacuum environment enables plasma to be generated in smaller areas rather than creating plasma in the entire processing volume of a chamber as found in typical vacuum plasma chambers. In some instances, the plasma can be generated in a rectangular shape that is smaller than a photomask that is undergoing cleaning to enable better cleaning of particular areas of the photomask. The inventors have observed that the small, generated plasma tends to arc and cause damage around the peripheral edges of the photomask as the plasma moves across the surface of the photomask.

Accordingly, the inventors have provided apparatus and methods for cleaning a photomask without damaging the peripheral edges of the photomask and with enhanced automatic clamping of the photomask during processing.

### SUMMARY

Methods and apparatus for handling of photomasks during AP plasma cleaning are provided herein.

In some embodiments, an atmospheric pressure plasma (APP) chamber for cleaning a photomask may comprise a plasma reactor with a plurality of reactor heads in the APP chamber, a photomask handling assembly positioned below the plasma reactor in the APP chamber, a set of stationary standoffs with each stationary standoff having a first end solidly mounted to the photomask handling assembly and a second end configured to contact an underside of the photomask, and a handling stage with an opening area configured to receive the photomask and a set of plates surrounding the opening area, wherein the set of plates are configured to automatically move towards the opening area to clamp the photomask when the handling stage moves vertically.

In some embodiments, the APP chamber may further comprise a motion guard assembly with a first portion mounted to the photomask handling assembly and a second portion mounted to the handling stage which is configured to stop horizontal motion of the handling stage until a bottom surface of the handling stage is above each of the second end of the set of stationary standoffs; a rotation control post with a straight vertical side and a first end solidly mounted to the photomask handling assembly and a second end with an angled profile and a rotation assembly with a lower portion extending through a bottom surface of the handling stage and configured to contact the straight vertical side of the rotation control post to maintain a rotation orientation and to contact the angled profile of the second end of the rotation control post to change the rotation orientation of an upper portion internal to the handling stage, wherein the upper portion is configured to adjust a clamping force applied to the set of plates when the rotation orientation is altered; at least one sensor positioned in the APP chamber and configured to detect when the set of plates or the photomask would interfere with the plurality of reactor heads of the plasma reactor; where the handling stage is configured to apply a clamping force of approximately 0.25 pounds to approximately 10 pounds on each side of the photomask; where the handling stage has springs that are configured to apply a force to the set of plates to clamp the photomask; where the handling stage is configured to limit motion with stops for at least two plates of the set of plates; a controller configured to move the handling stage in a vertical direction to clamp and unclamp the photomask; where the controller is configured to move the handling stage in a horizontal direction; and/or where the controller is configured to move the handling stage in the horizontal direction based upon a cleaning process that controls a speed, back and forth motion, and position of the handling stage.

In some embodiments, an APP chamber for cleaning a photomask may comprise a plasma reactor with a plurality of reactor heads in the APP chamber, a photomask handling assembly positioned below the plasma reactor in the APP chamber, a set of stationary standoffs with each stationary standoff having a first end solidly mounted to the photomask handling assembly and a second end configured to contact an underside of the photomask, a handling stage with an opening area configured to receive the photomask and a set of plates surrounding the opening area, wherein the set of plates are configured to automatically move towards the opening area to clamp the photomask when the handling stage moves vertically, and a controller configured to move the handling stage in a vertical direction to clamp and unclamp the photomask and configured to move the handling stage in a horizontal direction for photomask processing and where the controller is configured to detect placement of the photomask on the set of stationary standoffs, raise the handling stage in an upward motion to automatically lift the photomask off of the set of stationary standoffs and clamp the photomask within the set of plates, pause the upward motion of the handling stage below a processing height, detect if the photomask and the set of plates are in a settled position on the handling stage, raise the handling stage upwards to the processing height, move the handling stage in one or more horizontal directions according to a photomask cleaning recipe, and lower the handling stage in a downward motion to automatically unclamp the photomask from the set of plates and set the photomask on the set of stationary standoffs.

In some embodiments, the APP chamber further comprises a motion guard assembly with a first portion mounted to the photomask handling assembly and a second portion mounted to the handling stage which is configured to stop horizontal motion of the handling stage until a bottom surface of the handling stage is above each of the second end of the set of stationary standoffs; a rotation control post with a straight vertical side and a first end solidly mounted to the photomask handling assembly and a second end with an angled profile and a rotation assembly with a lower portion extending through a bottom surface of the handling stage and configured to contact the straight vertical side of the rotation control post to maintain a rotation orientation and to contact the angled profile of the second end of the rotation control post to change the rotation orientation of an upper portion internal to the handling stage, wherein the upper portion is configured to adjust a clamping force applied to the set of plates when the rotation orientation is altered; at least one sensor positioned in the APP chamber and configured to detect when the set of plates or the photomask are settled on the handling stage; where the handling stage is configured to apply a clamping force of approximately 0.25 pounds to approximately 10 pounds on each side of the photomask; where the handling stage has springs that are configured to apply a force to the set of plates to clamp the photomask; and/or where the handling stage is configured to limit motion with stops for at least two plates of the set of plates.

In some embodiments, a photomask handling assembly to support a photomask in an APP may comprise an opening area of a photomask handling stage configured to receive the photomask and a set of plates surrounding the opening area of the photomask handling stage, wherein the set of plates are configured to automatically move towards the opening area to clamp the photomask when the photomask handling stage moves vertically.

In some embodiments, the photomask handling assembly may further comprise a set of stationary standoffs with each stationary standoff having a first end solidly mounted and a second end configured to contact an underside of a photomask, where the photomask handling stage has a set of through openings that are configured to allow the set of stationary standoffs to pass through the photomask handling stage as the photomask handling stage moves vertically; a rotation control post with a straight vertical side and a first end solidly mounted and a second end with an angled profile and a rotation assembly with a lower portion extending through a bottom surface of the photomask handling stage and configured to contact the straight vertical side of the rotation control post to maintain a rotation orientation and to contact the angled profile of the second end of the rotation control post to change the rotation orientation of an upper portion internal to the photomask handling stage, where the upper portion is configured to adjust a clamping force applied to the set of plates when the rotation orientation is altered; a motion guard assembly with a first portion solidly mounted and a second portion mounted to the photomask handling stage which is configured to stop horizontal motion of the photomask handling stage until a bottom surface of the photomask handling stage is above a set of stationary standoffs; at least one sensor positioned in a vicinity of the photomask handling assembly and configured to detect when the set of plates or the photomask would interfere with a reactor head of a plasma reactor of an atmospheric pressure plasma chamber; where the photomask handling stage is configured to apply a clamping force of approximately 0.25 pounds to approximately 10 pounds on each side of the photomask; where the photomask handling stage has springs that are configured to apply a force to the set of plates to clamp the photomask; where the photomask handling stage is configured to limit motion with stops for at least two plates of the set of plates; and/or a controller configured to move the photomask handling stage in a vertical direction to clamp and unclamp the photomask and in horizontal direction for photomask processing.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a cross-sectional view of an APP chamber in an initial photomask reception position in accordance with some embodiments of the present principles.

FIG. 2 depicts a cross-sectional view of an APP chamber with a photomask handling assembly at a first height position in accordance with some embodiments of the present principles.

FIG. 3 depicts a cross-sectional view of an APP chamber with a photomask handling assembly at a processing height position in accordance with some embodiments of the present principles.

FIG. 4 depicts a cross-sectional view of an APP chamber with a photomask handling assembly in a plasma ignition position in accordance with some embodiments of the present principles.

FIG. 5 depicts a cross-sectional view of an APP chamber with a photomask handling assembly in a photomask processing position in accordance with some embodiments of the present principles.

FIG. 6 depicts a top-down view of a handling stage with a set of plates in an unclamped position in accordance with some embodiments of the present principles.

FIG. 7 depicts a top-down view of a handling stage with a set of plates in a clamped position in accordance with some embodiments of the present principles.

FIG. 8 depicts a top-down view of a handling stage checked for unsettled plates or photomask in accordance with some embodiments of the present principles.

FIG. 9 depicts an isometric view of a bottom surface of a handling stage in accordance with some embodiments of the present principles.

FIG. 10 depicts cross-sectional views of a lower portion of a rotation assembly in contact with a rotation control post in accordance with some embodiments of the present principles.

FIG. 11 depicts an isometric view of a clamping assembly internal to a handling stage in accordance with some embodiments of the present principles.

FIG. 12 depicts an isometric view of a top surface of a handling stage in accordance with some embodiments of the present principles.

FIG. 13 depicts a cross-sectional view of a handling stage in accordance with some embodiments of the present principles.

FIG. 14 depicts an isometric view of a motion guard assembly of a handling stage in accordance with some embodiments of the present principles.

FIG. 15 depicts a cross-sectional view of angled profiles of a rotation control post in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The present principles provide a photomask handling assembly and operation for atmospheric pressure plasma (APP) chambers. In some embodiments, a method for automatically clamping and unclamping of plates on all four sides of a photomask and moving the photomask under a plasma reactor at a programmable speed, distance, and/or pattern is provided. The present principles also have the advantage of allowing for increased throughput and enhanced reliability. Another advantage is the ability of the handling stage of the photomask handling assembly to inhibit particle generation during operation. The handling stage is also void of electrical encumbrances (e.g., wires, motors, power source requirements, etc.), as the clamping operation is mechanically based.

Traditional cleaning processes and holding apparatus for photomasks can cause edge arcing issues during the APP process. The present principles utilize dummy plates of the same material (or dissimilar materials), touching on all four sides, to provide a continuous surface that eliminates the edge arcing of the photomask. The present methods and apparatus allow for moving a photomask under the plasma reactor at a selectable speed and distance for a given amount of time. Dummy plates surround the photomask are in contact with all four sides of the photomask and at the same height as the top surface of the photomask. The dummy plates eliminate arcing edge effects on the photomask by adding additional surface areas that extend from the photomask edges. The dummy plates may be formed from, but not meant to be limited to, fused silica/quartz and the like. When inserted into the plasma reactor, the photomask is placed on a set of chamber stand-offs (or a “nest” as used herein) by a robot end effector through a door in the APP chamber. The handling stage sits below the photomask after the photomask is placed on the nest. The handling stage then raises and picks the photomask up off of the nest. An assembly inside the handling stage is mechanically timed with the upward motion and closes/clamps the dummy plates around the photomask after the photomask is fully seated on the handling stage. The internal assembly of the handling stage may also be pneumatic or motor driven. After the handling stage picks up the photomask, the handling stage moves upwards to the processing height (set distance from the plasma reactor that is used for during cleaning of the photomask).

The photomask handling assembly then causes the handling stage to translate sideways and centers the largest dummy plate (or “ignition plate” as used herein) under the plasma reactor. The plasma is ignited on the ignition plate until the plasma stabilizes. The distance of the photomask to the plasma reactor during processing is determined by the cleaning process. In some embodiments, a translate position at an intermediate height below a processing height is used to run the handling stage through a set of sensors to ensure that the photomask and dummy plates are fully seated before moving up to a process height. The sensors facilitate in avoiding damage to the plasma reactor caused by unsettled photomasks or dummy plates. Purging the APP chamber of atmospheric gasses can be accomplished with a separate purge line or by turning on the plasma gasses for some amount of time prior to igniting the plasma. The purge will come from the top and exhaust at the bottom. The top to bottom purge flow ensures that the gasses progress downward to below the photomask, preventing particles from moving upward and landing on the photomask.

The handling stage is then moved under the reactor which also moves the photomask under the reactor and past the reactor to the other side of the plasma reactor. The moving of the photomask under the plasma ensures even treatment of the entire photomask. In some embodiments, the photomask handling assembly can the move the handling stage, for example, at full stroke back and forth for a set process time. The handling stage can also be programmed to move at specific patterns (specific pitches and frequencies) or at random patterns. After the cleaning process is completed, the photomask handling assembly moves the handling stage so that the ignition plate is again centered under the reactor and the plasma is turned off. The handling stage then laterally moves to the side to the initial automation position and begins lowering. As the handling stage lowers, the internal mechanism automatically opens/unclamps the dummy plates from the photomask and the photomask is set on the nest. The photomask is now ready for the robot end effector to pick up and remove the photomask from the APP chamber.

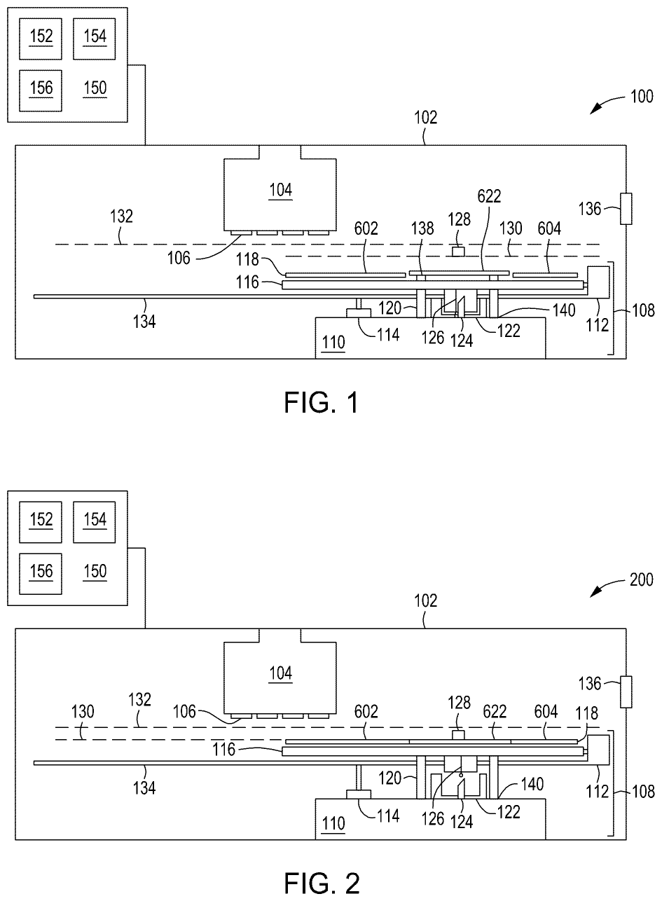

An example of the above process is shown in FIGS. 1-5. In a view 100 of FIG. 1, an APP chamber 102 for cleaning photomasks is depicted in an initial state for receiving a photomask. The APP chamber 102 includes a photomask handling assembly 108 and a plasma reactor 104 with at least one reactor head 106. The APP chamber 102 uses the reactor head 106 to provide plasma to treat a photomask that is undergoing a cleaning process in the APP chamber 102. Unlike vacuum plasma chambers that produce plasma throughout the processing volume, the atmospheric plasma of the APP chamber 102 is controllable to produce a localized rectangular shape plasma area around the reactor head 106. The localized plasma allows for specific areas of the photomask to be treated once or multiple times by varying a cleaning recipe for the APP chamber 102. The photomask handling assembly 108 includes a base 110 and a handling stage 116 which moves laterally on a lateral guide assembly 134 powered by a lateral actuator 112 and moves vertically powered by a vertical actuator 114.

The handling stage 116 includes a set of plates 118 that is used to automatically clamp and unclamp a photomask 622 to the handling stage 116. The set of plates 118 includes at least a left plate 602 (ignition plate) and a right plate 604 (see FIG. 6). The handling stage 116 also includes a rotation assembly 126 that extends through a lower portion of the handling stage 116 and makes contact with a rotation control post 124 that is mounted to the base 110 of the photomask handling assembly 108. The handling stage 116 may also have an upper portion of a motion guard assembly 122 attached to the lower portion of the handling stage 116. A lower portion of the motion guard assembly 122 is attached to the base 110 of the photomask handling assembly 108. A set of stationary standoffs 120 are also part of the photomask handling assembly 108. The first ends 140 of the set of stationary standoffs 120 are solidly mounted to the base 110 of the photomask handling assembly 108.

When the APP chamber 102 is ready to receive a photomask for processing, the photomask 622 is placed on the second ends 138 of the set of stationary standoffs 120 by an end effector (not shown) through a sealable door 136. The second ends 138 of the set of stationary standoffs 120 contact a lower surface of the photomask at three or more points (the set of stationary standoffs 120 includes at least three standoffs). The set of stationary standoffs 120 protrude through the handling stage 116 such that in the initial loading position, the second ends 138 of the set of stationary standoffs 120 are above a top surface of the handling stage 116. The location of the sealable door 136 may vary (e.g., on an end of the APP chamber 102 as shown or on a side of the APP chamber 102, etc.). The APP chamber 102 also includes at least one sensor 128 that is configured to detect when the set of plates 118 and/or the photomask are unsettled and would interfere with the reactor head 106 of the plasma reactor 104 during processing. The sensor 128 is positioned at a first height position 130 that is lower in height than a second height position 132 or process position.

A controller 150 controls the operation of the APP chamber 102 using a direct control of the APP chamber 102 or alternatively, by controlling the computers (or controllers) associated with the APP chamber 102. The controller 150 may be used to control the clamping and unclamping of the photomask by the handling stage 116 through the vertical movement of the handling stage 116 and/or the cleaning process by controlling the pattern and timing of the cleaning through control of the lateral movement of the handling stage 116. In operation, the controller 150 also enables data collection and feedback from the respective systems to optimize performance of the APP chamber 102. The controller 150 generally includes a Central Processing Unit (CPU) 152, a memory 154, and a support circuit 156. The CPU 152 may be any form of a general-purpose computer processor that can be used in an industrial setting. The support circuit 156 is conventionally coupled to the CPU 152 and may comprise a cache, clock circuits, input/output subsystems, power supplies, and the like. Software routines, such as a method as described herein may be stored in the memory 154 and, when executed by the CPU 152, transform the CPU 152 into a specific purpose computer (controller 150). The software routines may also be stored and/or executed by a second controller (not shown) that is located remotely from the APP chamber 102.

The memory 154 is in the form of computer-readable storage media that contains instructions, when executed by the CPU 152, to facilitate the operation of the semiconductor processes and equipment. The instructions in the memory 154 are in the form of a program product such as a program that implements the cleaning of photomasks based on the present principles. The program code may conform to any one of a number of different programming languages. In one example, the disclosure may be implemented as a program product, such as, for example, a photomask cleaning recipe, stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

The set of plates 118 are depicted in more detail in a view 600 of FIG. 6. The set of plates 118 are movably affixed to the handling stage 116. The set of plates 118 are held captive but allowed to move enough to allow for clamping and unclamping motions. The terms left, right, top, and bottom denote the orientation shown in FIG. 6 and is understood to change accordingly when viewed from different positions. The left plate 602 or ignition plate (largest plate), the right plate 604, the top plate 606, and the bottom plate 608 move outward 610 from a center 612 of a reception area 614 (opening area) for a photomask of the handling stage 116 when in an initial position to accept a photomask 622. The ignition plate (left plate 602) is generally sized so that all reactor heads fit over the ignition plate simultaneously. The photomask 622 is placed in the reception area 614 by an end effector through the sealable door 136 (see FIG. 1). Referring to the view 200 of FIG. 2, the vertical actuator 114 moves the handling stage 116 upward to a first height position 130 below the second height position 132 or processing position.

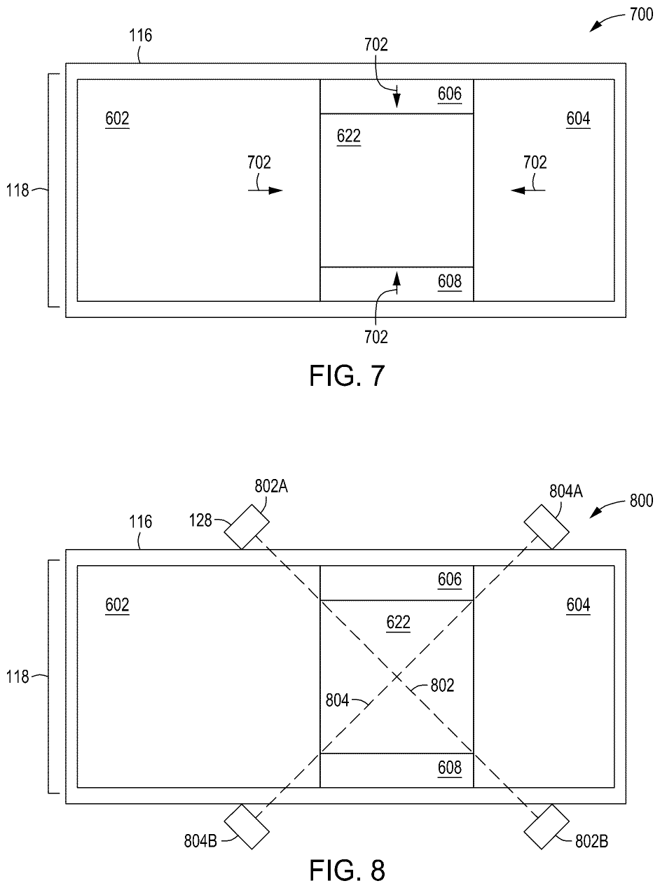

As the handling stage 116 moves upward, the lower portion of the rotation assembly moves along a straight vertical side of the rotation control post 124 and then slowly across an angled profile of the rotation control post 124, applying an inward force 702 on the set of plates 118 which in turn apply inward forces on the photomask 622 as depicted in a view 700 of FIG. 7 to automatically clamp the photomask 622 in position on the handling stage 116. While the applied force facilitates in preventing gaps between the set of plates 1818 and the photomask 622, the applied force also aids in preventing movement of the photomask 622 when the handling stage 116 is raised or lowered during processing. The applied force should be enough to keep the photomask 622 from moving when the handling stage 116 moves and less than a force that would break or damage the photomask 622. In some embodiments, the inward force 702 (applied force) may be from approximately 0.25 lbs of force to approximately 10 lbs of force applied to the photomask 622 as the handling stage 116 is raised upwards. In some embodiments, the inward force 702 (applied force) may be from approximately 3 lbs of force to approximately 5 lbs of force applied to the photomask 622 as the handling stage 116 is raised upwards. The handling stage 116 inner assembly workings are discussed in greater detail below.

When the handling stage 116 reaches the first height position 130, in some embodiments, a check may be made to determine if the set of plates 118 and the photomask 622 are in a settled position using a sensor 128 as depicted in FIG. 2 and also as depicted in a view 800 of FIG. 8. In FIG. 8, two sensor transmitters 802A, 804A use a light beam directed at two sensor receivers 802B, 804B. In some embodiments, the handling stage 116 is moved back and forth under the sensor 128 to check all areas of the set of plates 118 and the photomask 622. If the set of plates 118 or the photomask 622 are in an unsettled position, the beams 802, 804 of light will be broken and the undesirable condition will be detected. If the set of plates 118 or the photomask 622 is in an unsettled position when processing is performed, the reactor head 106 will strike the set of plates 118 and/or the photomask 622 causing damage to the APP chamber 102 and the photomask 622/set of plates 118. When an unsettled condition is detected, the cleaning process is immediately halted to prevent chamber damage. The sensors may also be aligned in other configurations such as with parallel beams and the like as the configuration of FIG. 8 is not meant to be limiting. Visual or audible warnings may also be given to alert chamber users of the errant conditions.

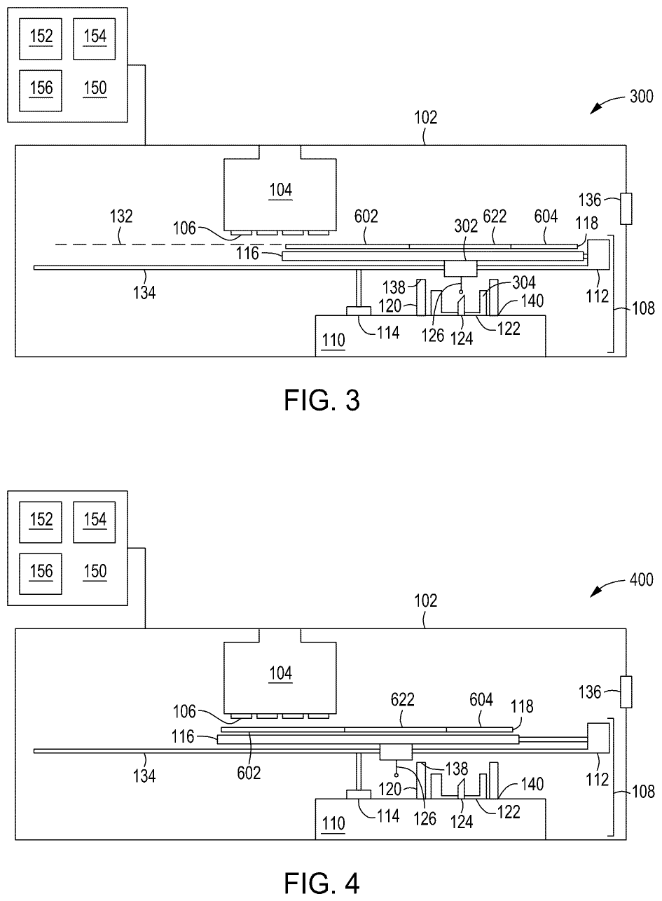

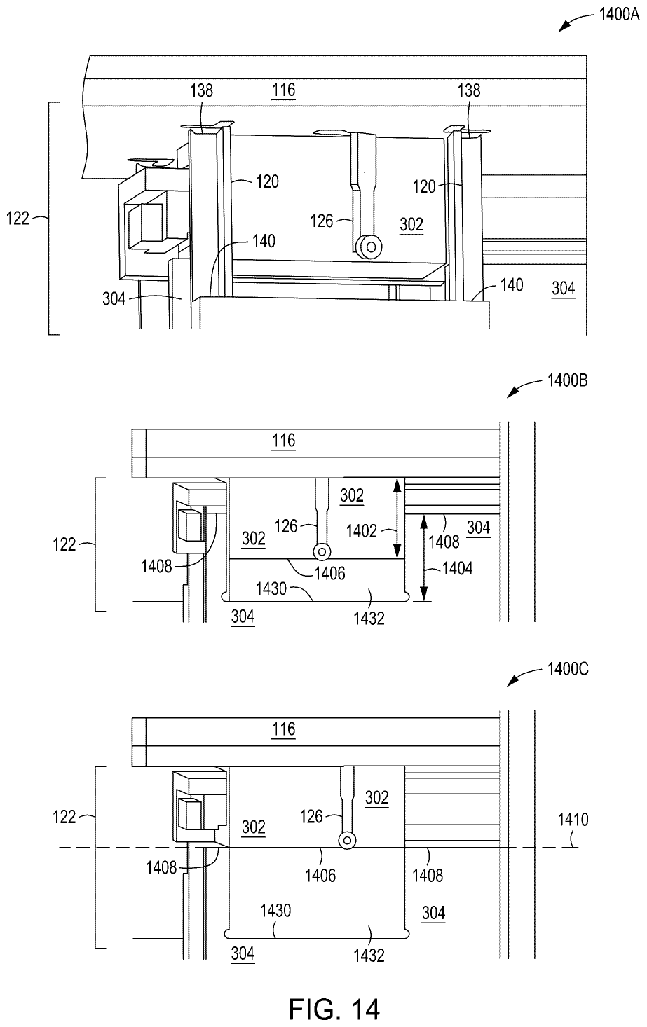

As depicted in a view 300 of FIG. 3, if an errant condition is not detected at the first height position 130, the vertical actuator 114 lifts the handling stage 116 to the second height position 132 or processing position. The upper portion 302 of the motion guard assembly 122 is clear of the lower portion 304 (see in more detail in FIG. 14 discussed below). When the conditions of the motion guard assembly 122 are satisfied in the vertical direction (motion guard assembly prevents lateral movement until the second ends 138 of the set of stationary standoffs are cleared by the handling stage 116). As depicted in a view 400 of FIG. 4, the handling stage 116 is moved laterally along the lateral guide assembly 134 by the lateral actuator 112 until the left plate 602 or ignition plate is positioned directly under the plasma reactor 104. The plasma reactor 104 then ignites plasma between the reactor head 106 and the ignition plate. Plasma is not ignited over the photomask to prevent plasma ignition damage to the photomask.

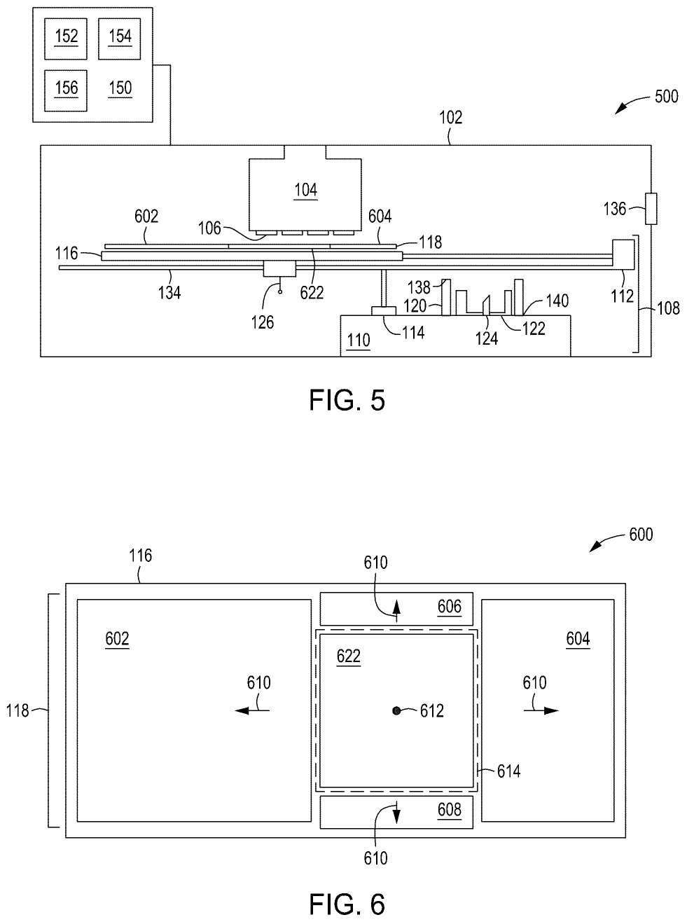

Once the plasma has stabilized, the handling stage 116 begins moving the photomask under the plasma reactor 104 to clean the photomask as depicted in a view 500 of FIG. 5. The controller 150 may be programmed with a variety of cleaning recipes which can include back and forth lateral motions of the handling stage 116 under the plasma reactor 104 and/or other recipes such as step and stop, step and move back and forth, fast or slow movements followed by slow or fast movements, etc. The photomask handling assembly 108 can be programmed to perform any number of cleaning profiles including multiple cleaning profiles in a single cleaning session and the like. When the cleaning program is completed, the controller 150 moves the handling stage 116 laterally and lowers the handling stage 116 back to the initial state depicted in the view 100 of FIG. 1. As the handling stage 116 is lowered, the rotation assembly 126 contacts the rotation control post 124 and automatically unclamps the photomask for removal by the end effector.

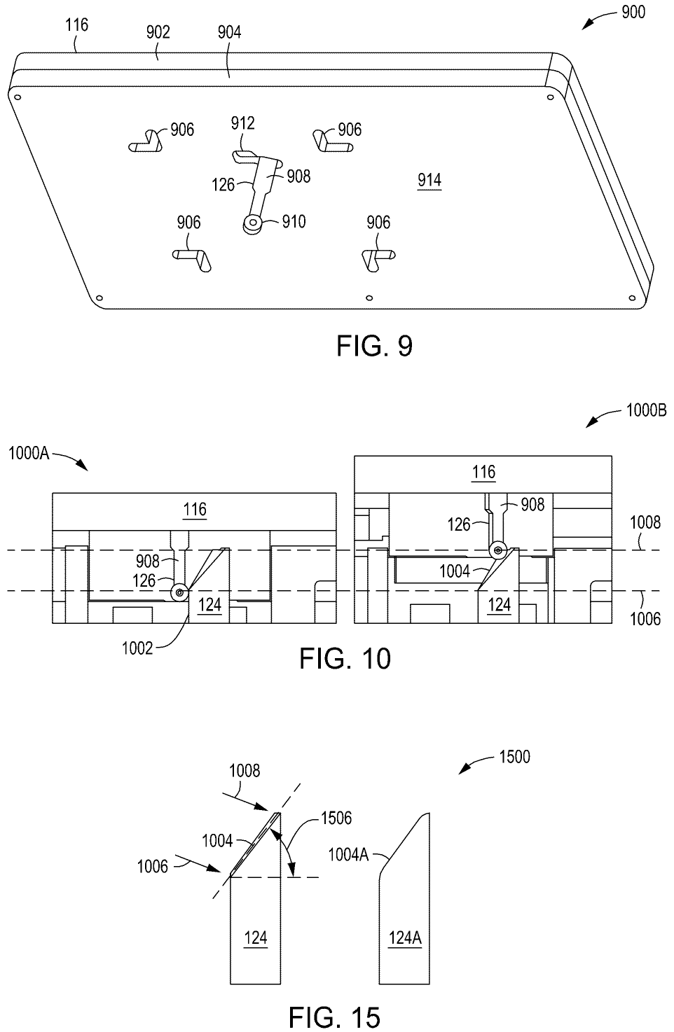

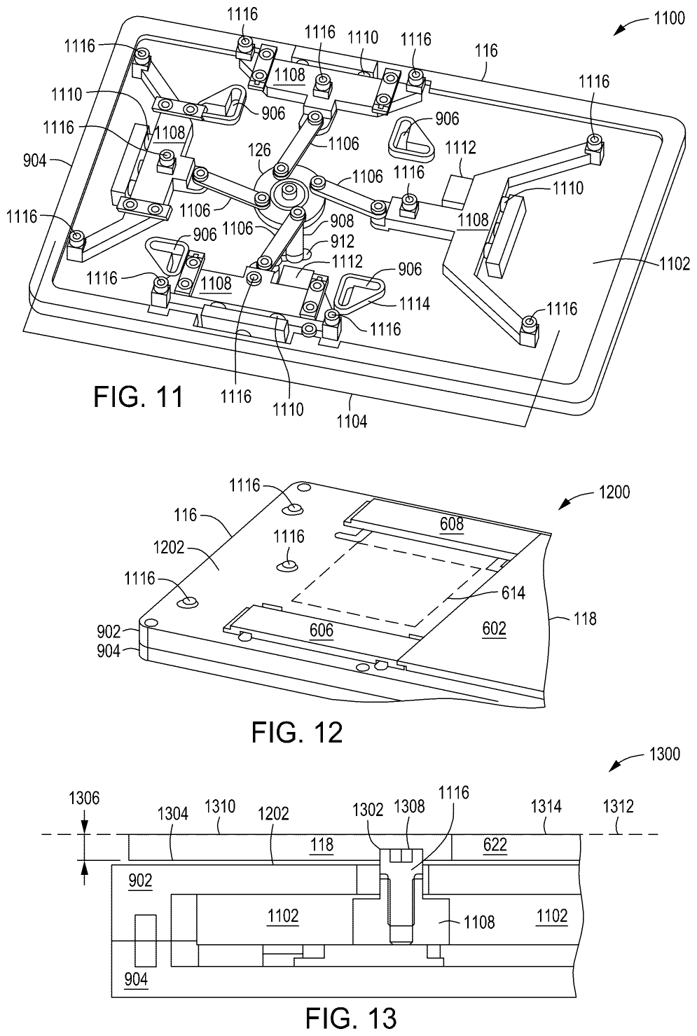

Details of the handling stage 116 are now provided. A view 900 of FIG. 9 depicts a bottom surface 914 of a lower portion 904 of the handling stage 116. The handling stage 116 has an upper portion 902 and the lower portion 904 which stack together to form a hollow center space 1102 to house a clamping assembly 1104 which is controlled by the rotation assembly 126 (see view 1100 of FIG. 11). The lower portion 908 of the rotation assembly 126 protrudes through a rotation assembly slot 912 in the lower portion 904 of the handling stage 116 and may include a bearing 910 that makes contact with the rotation control post 124 (discussed in FIG. 10 below). Through holes 906 are also formed in the lower portion 904 and the upper portion 902 of the handling stage 116 to allow the set of stationary standoffs 120 to protrude through the handling stage 116 in order to support a photomask at an initial photomask reception stage of a cleaning process. The bearing 910 of the lower portion 908 of the rotation assembly 126 makes contact with a straight vertical side 1002 of the rotation control post 124 as depicted in view 1000A of FIG. 10. As the bearing rides up the straight vertical side 1002 of the rotation control post 124, the set of plates 118 are forced outward as depicted in view 600 of FIG. 6 discussed above. The rotation assembly slot 912 may be slightly curved to allow the lower portion to move in an arcing motion, permitting the rotation assembly to apply and remove forces from the set of plates 118.

As the handling stage 116 moves upward, the bearing 910 of the lower portion 908 of the rotation assembly 126 will begin to ride on the angled profile 1004 of the rotation control post 124 at the upper end of the rotation control post 124 as depicted in a view 1000B of FIG. 10, allowing forces to be applied to a photomask at the center of the set of plates 118 on the handling stage 116. The forces begin to be applied at the start 1006 of the angled profile 1004 and are increased until the end 1008 of the angled profile 1004. As depicted in a view 1500 of FIG. 15, the angle 1506 of the angled profile 1004 may be altered to shorten or lengthen the time over which the full force is applied to the photomask for the rotation control post 124. The start 1006 of the angled profile 1004 and the end 1008 of the angled profile 1004 may be altered to reduce sudden application of forces which might cause jarring and particle generation as depicted in a view 1500 of FIG. 15. Smoothing of the start 1006 and the end 1008 of the angled profile 1004 to yield the smoothed angled profile 1004A of rotation control post 124A helps to reduce the jarring during application and removal of the forces. The profile of rotation control post 124 or 124A is not meant to be limiting as other profiles may be used as well to modify the application (linearity of applied forces, rate of applied forces, etc.) of the forces applied to the photomask.

In the view 1100 of FIG. 11, the rotation assembly 126 and the clamping assembly 1104 internal to the handling stage 116 is depicted. In some embodiments, the rotation assembly 126 is connected via links 1106 to force applicators 1108 that are pushed inward towards the rotation assembly 126 via springs 1110 to apply forces to the set of plates 118. In some embodiments, two of the four force applicators 1108 have stops 1112 that prevent the two force applicators 1108 from applying force against the photomask after reaching the stops 1112. The two remaining force applicators without stops then drive the photomask into the two force applicators with stops to ensure that no gap is left around the entire perimeter of the photomask as depicted in the view 700 of FIG. 7. By using the rotation control post 124 and the rotation assembly 126 to control the clamping assembly 1104, the photomask is clamped and unclamped automatically without the use of electrical mechanisms and associated wiring (which can generate particles and increase costs) and power requirements, forming a robust automatic clamping mechanism at a lower cost. In addition, the through holes 906 for the set of stationary standoffs 120 have walls 1114 that seal the hollow center space 1102 that houses the clamping assembly 1104 from the external environment of the set of stationary standoffs 120. The isolation of the hollow center space 1102 from the external environment ensures that particles are not generated by the motion of the clamping assembly 1104 during processing of the photomask. The only breach to the external environment might possibly be the rotation assembly slot 912 at the bottom of the handling stage 116. However, purge gases and process gases flow through the processing volume and downward exiting out of the lower portion of the APP chamber. Any particles generated through the rotation assembly slot 912 would be quickly carried out through the bottom of the chamber and would not reach the photomask being processed.

As depicted in a view 1200 of FIG. 12, the set of plates 118 are attached to the force applicators 1108 of the clamping assembly 1104 via posts 1116 that are connected to the force applicators 1108 and extend through and beyond the upper surface 1202 of the upper portion 902 of the handling stage 116. The posts 1116 engage with the set of plates by protruding into a recess 1302 in a bottom surface 1304 of the set of plates 118 as depicted in a view 1300 of FIG. 13. The recess 1302 may be threaded, non-threaded, dovetailed, and/or have other retention methods such as epoxy, friction fit, and the like to facilitate in retaining the posts 1116. Likewise, the posts 1116 may have an upper end that is threaded, non-threaded, dovetails, and/or have other retention methods such as epoxy, friction fit, and the like. In some embodiments, the set of plates 118 are not retained by the posts 1116 in the vertical direction, only the lateral directions. The thickness 1306 of the set of plates 118 is within the photomask thickness specifications cited in the SEMI Standards Organization's published specifications. During setup of an APP chamber, shims (not shown) can be inserted between the bottom surface 1304 of the set of plates 118 and the upper surface 1202 of the upper portion 902 of the handling stage 116 and/or on a top surface 1308 of the posts 1116 until a top surface 1310 of the set of plates 118 and a top surface 1314 of the photomask 622 are aligned to provide an even and continuous surface 1312. Similarly, shims may be placed in the reception area 614 (see FIGS. 6 and 12) for the photomask 622 if the photomask 622 top surface 1314 is lower than the top surface 1310 of the set of plates 118.

Views of FIG. 14 depict further details of the motion guard assembly 122 depicted in FIGS. 1-5. The second ends 138 of the set of stationary standoffs 120 must clear the handling stage 116 prior to any lateral movement of the handling stage 116 as depicted in view 1400A of FIG. 14. To ensure that lateral movement of the handling station is not possible prior to the clearing event, a motion guard assembly 122 with an upper portion 302 and a lower portion 304 are used to block any lateral movement of the handling stage 116. The upper portion 302 is affixed to the lower surface of the handling stage 116 and engages with the lower portion 304 of the motion guard assembly 122 that is solidly attached to the base 110 by slotting into a cutout 1432 in the lower portion 304. The height 1402 of the upper portion 302 is equal to the depth 1404 of the cutout 1432 of the lower portion 304 from the upper edge 1408 of the lower portion to the bottom 1430 of the cutout 1432. In order for lateral motion to occur, the handling stage 116 must be lifted high enough in the vertical direction such that the lower edge 1406 of the upper portion 302 clears 1410 the upper edge 1408 of the lower portion 304 of the motion guard assembly 122 as depicted a view 1400C of FIG. 14.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1.-20. (canceled)

21. An chamber for cleaning a photomask, comprising:
a plasma reactor; and
a photomask handling assembly positioned below the plasma reactor, the photomask handling assembly including a handling stage with an opening area configured to receive the photomask and a set of plates surrounding the opening area, wherein the set of plates are configured to move towards the opening area to clamp the photomask.

22. The chamber of claim 21, further comprising:
a set of stationary standoffs with each stationary standoff having a first end solidly mounted to the photomask handling assembly and a second end configured to contact an underside of the photomask through an opening in the handling stage.

23. The chamber of claim 21, wherein the plasma reactor includes a plurality of reactor heads in the chamber.

24. The chamber of claim 21, further comprising:
a rotation assembly having a rotating portion internal to the handling stage, the rotating portion coupled to the set of plates, wherein the rotating portion is configured to adjust a clamping force applied to the set of plates when a rotation orientation of the rotating portion is altered.

25. The chamber of claim 24, wherein the rotation assembly is coupled to the set of plates via links.

26. The chamber of claim 21, wherein the handling stage has an internal assembly that is pneumatic or motor driven.

27. The chamber of claim 21, further comprising:
a rotation control post with a straight vertical side and a first end solidly mounted to the photomask handling assembly and a second end with an angled profile; and
a rotation assembly with a lower portion extending through a bottom surface of the handling stage and configured to contact the straight vertical side of the rotation control post to maintain a rotation orientation and to contact the angled profile of the second end of the rotation control post to change the rotation orientation of an upper portion internal to the handling stage, wherein the upper portion is configured to adjust a clamping force applied to the set of plates when the rotation orientation is altered.

28. The chamber of claim 21, further comprising:
at least one sensor positioned in the chamber and configured to detect when the set of plates or the photomask would interfere with a plurality of reactor heads of the plasma reactor.

29. The chamber of claim 21, wherein at least one of:
the handling stage is configured to apply a clamping force of approximately 0.25 pounds to approximately 10 pounds on each side of the photomask;
the handling stage has springs that are configured to apply a force to the set of plates to clamp the photomask; or
the handling stage is configured to limit motion with stops for at least two plates of the set of plates.

30. The chamber of claim 21, further comprising:
a controller configured to move the handling stage in a vertical direction to clamp and unclamp the photomask.

31. The chamber of claim 21, further comprising:
a controller configured to move the handling stage in a horizontal direction based upon a cleaning process that controls a speed, back and forth motion, and position of the handling stage.

32. A photomask handling assembly to support a photomask, comprising:
a handling stage having an opening area configured to receive the photomask, and a set of plates surrounding the opening area, wherein the set of plates are configured to move towards the opening area to clamp the photomask.

33. The photomask handling assembly of claim 32, wherein the set of plates are configured to automatically move towards the opening area to clamp the photomask when the handling stage moves vertically.

34. The photomask handling assembly of claim 32, further comprising:
a set of stationary standoffs with each stationary standoff having a first end solidly mounted and a second end configured to contact an underside of the photomask, wherein the handling stage has a set of through openings that are configured to allow the set of stationary standoffs to pass through the handling stage as the handling stage moves vertically.

35. The photomask handling assembly of claim 34, further comprising at least one of:
a) a rotation control post with a straight vertical side and a first end solidly mounted and a second end with an angled profile; and
a rotation assembly with a lower portion extending through a bottom surface of the handling stage and configured to contact the straight vertical side of the rotation control post to maintain a rotation orientation and to contact the angled profile of the second end of the rotation control post to change the rotation orientation of an upper portion internal to the handling stage, wherein the upper portion is configured to adjust a clamping force applied to the set of plates when the rotation orientation is altered; or
b) a motion guard assembly with a first portion solidly mounted and a second portion mounted to the handling stage which is configured to stop horizontal motion of the handling stage until a bottom surface of the handling stage is above a set of stationary standoffs.

36. The photomask handling assembly of claim 32, further comprising:
a rotation assembly having a rotating portion internal to the handling stage, the rotating portion coupled to the set of plates, wherein the rotating portion is configured to adjust a clamping force applied to the set of plates when a rotation orientation of the rotating portion is altered.

37. The photomask handling assembly of claim 36, wherein the rotation assembly is coupled to the set of plates via links.

38. The photomask handling assembly of claim 32, wherein the handling stage includes an internal assembly that is pneumatic or motor driven.

39. The photomask handling assembly of claim 32, wherein the handling stage is configured to apply a clamping force of approximately 0.25 pounds to approximately 10 pounds on each side of the photomask.

40. The photomask handling assembly of claim 32, wherein at least one of:
the handling stage has springs that are configured to apply a force to the set of plates to clamp the photomask; or
the handling stage is configured to limit motion with stops for at least two plates of the set of plates.
